(19) United States
(12) Patent Application Publication
(10) Pub. No.: US 2025/0023320 A1
(43) Pub. Date: Jan. 16, 2025

(54) PROTECTIVE CASE FOR SEMICONDUCTOR LIGHT EMITTING DEVICE, METHOD OF MANUFACTURING THE SAME, AND SEMICONDUCTOR LIGHT EMITTING APPARATUS

(71) Applicant: ROHM CO., LTD., Kyoto-shi (JP)

(72) Inventor: Akito SHINODA, Kyoto-shi (JP)

(21) Appl. No.: 18/900,207

(22) Filed: Sep. 27, 2024

Related U.S. Application Data
(63) Continuation of application No. PCT/JP2023/018547, filed on May 18, 2023.

(30) Foreign Application Priority Data
May 25, 2022 (JP) 2022-084907

(51) Int. Cl. H01S 5/02234; H01S 5/02257

(52) U.S. Cl. CPC H01S 5/02234; H01S 5/02257

(57) ABSTRACT

A protective case includes a protective cover and a transparent plate. A first bottom surface of the protective cover is provided with a bottom opening. A front surface of the protective cover is provided with a front opening. The front opening of the protective cover extends to the first bottom surface of the protective cover. A transparent plate is attached to the front surface of the protective cover to close the front opening. The first bottom surface of the protective cover and the second bottom surface of the transparent plate are flush with each other.

### TECHNICAL FIELD

The present disclosure relates to a protective case for a semiconductor light emitting device, a method of manufacturing the same, and a semiconductor light emitting apparatus.

### BACKGROUND ART

Japanese Patent Laying-Open No. 2019-125614 (PTL 1) discloses a semiconductor laser device that includes a base substrate, a semiconductor laser device, a first cover, and a second cover.

### CITATION LIST

### Patent Literature

PTL 1: Japanese Patent Laying-Open No. 2019-125614

### BRIEF DESCRIPTION OF DRAWINGS

FIG. 1 is a schematic plan view of a protective case according to a first embodiment;

FIG. 2 is a schematic front view of a protective case according to the first and second embodiments;

FIG. 3 is a schematic side view of a protective case according to the first embodiment;

FIG. 4 is a schematic bottom view of a protective case according to the first embodiment;

FIG. 5 is a schematic plan view of a semiconductor light emitting apparatus according to the first embodiment;

FIG. 6 is a schematic front view of a semiconductor light emitting apparatus according to the first and second embodiments;

FIG. 7 is a schematic plan view of a semiconductor light emitting apparatus (excluding a protective case) according to the first and second embodiments;

FIG. 8 is a schematic cross-sectional view of a semiconductor light emitting apparatus according to the first and second embodiments taken along a cross-sectional line VIII-VIII illustrated in FIGS. 5 and 22;

FIG. 9 is a schematic cross-sectional view of a semiconductor light emitting apparatus according to the first embodiment, a modification of the first embodiment, and the second embodiment taken along a cross-sectional line IX-IX illustrated in FIGS. 5, 17, and 22;

FIG. 10 is a schematic cross-sectional view of a semiconductor light emitting apparatus according to the first embodiment taken along a cross-sectional line X-X illustrated in FIG. 5;

FIG. 11 is a schematic plan view illustrating a step of a method of manufacturing a protective case according to the first and third embodiments;

FIG. 12 is a schematic plan view illustrating a step subsequent to the step illustrated in FIG. 11 in the method of manufacturing a protective case according to the first embodiment;

FIG. 13 is a schematic cross-sectional view taken along a cross-sectional line XIII-XIII of the step illustrated in FIG. 12 in the method of manufacturing a protective case according to the first embodiment;

FIG. 14 is a schematic plan view illustrating a step subsequent to the steps illustrated in FIGS. 12 and 13 in the method of manufacturing a protective case according to the first embodiment;

FIG. 15 is a schematic cross-sectional view taken along a cross-sectional line XV-XV of the step illustrated in FIG. 14 in the method of manufacturing a protective case according to the first embodiment;

FIG. 16 is a schematic plan view illustrating a step subsequent to the steps illustrated in FIGS. 14 and 15 in the method of manufacturing a protective case according to the first embodiment, and a step subsequent to the steps illustrated in FIGS. 26 and 27 in the method of manufacturing a protective case according to the second embodiment;

FIG. 17 is a schematic plan view of a semiconductor light emitting apparatus according to a modification of the first embodiment;

FIG. 18 is a schematic cross-sectional view of the semiconductor light emitting apparatus according to a modification of the first embodiment taken along a cross-sectional line XVIII-XVIII illustrated in FIG. 17;

FIG. 19 is a schematic plan view of a protective case according to a second embodiment;

FIG. 20 is a schematic side view of a protective case according to the second embodiment;

FIG. 21 is a schematic bottom view of a protective case according to the second embodiment;

FIG. 22 is a schematic plan view of a semiconductor light emitting apparatus according to the second embodiment;

FIG. 23 is a schematic cross-sectional view of a semiconductor light emitting apparatus according to the second embodiment taken along a cross-sectional line XXIII-XXIII illustrated in FIG. 22;

FIG. 24 is a schematic plan view illustrating a step of a method of manufacturing a protective case according to the second embodiment;

FIG. 25 is a schematic cross-sectional view taken along a cross-sectional line XXV-XXV of the step illustrated in FIG. 24 in the method of manufacturing a protective case according to the second embodiment;

FIG. 26 is a schematic plan view illustrating a step subsequent to the steps illustrated in FIGS. 24 and 25 in the method of manufacturing a protective case according to the second embodiment;

FIG. 27 is a schematic cross-sectional view taken along a cross-sectional line XXVII-XXVII of the step illustrated in FIG. 26 in the method of manufacturing a protective case according to the second embodiment;

FIG. 28 is a schematic bottom view of a protective case according to a third embodiment;

FIG. 29 is a schematic plan view of a semiconductor light emitting apparatus according to the third embodiment;

FIG. 30 is a schematic front view of a semiconductor light emitting apparatus according to the third embodiment;

FIG. 31 is a schematic partially enlarged cross-sectional view of a semiconductor light emitting apparatus according to the third embodiment taken along a cross-sectional line XXXI-XXXI illustrated in FIG. 29;

FIG. 32 is a schematic partially enlarged cross-sectional view of a semiconductor light emitting apparatus according to the third embodiment taken along a cross-sectional line XXXII-XXXII illustrated in FIG. 29;

FIG. 33 is a schematic plan view of a semiconductor light emitting apparatus (excluding a protective case and a bonding member) according to the third embodiment;

FIG. 34 is a schematic plan view illustrating a step subsequent to the step illustrated in FIG. 11 in the method of manufacturing a protective case according to the third embodiment;

FIG. 35 is a schematic cross-sectional view taken along a cross-sectional line XXXV-XXXV of the step illustrated in FIG. 34 in the method of manufacturing a protective case according to the third embodiment;

FIG. 36 is a schematic plan view illustrating a step subsequent to the steps illustrated in FIGS. 34 and 35 in the method of manufacturing a protective case according to the third embodiment;

FIG. 37 is a schematic cross-sectional view taken along a cross-sectional line XXXVII-XXXVII of the step illustrated in FIG. 36 in the method of manufacturing a protective case according to the third embodiment;

FIG. 38 is a schematic plan view illustrating a step subsequent to the steps illustrated in FIGS. 36 and 37 in the method of manufacturing a protective case according to the third embodiment;

FIG. 39 is a schematic partial enlarged cross-sectional view illustrating the method of manufacturing a semiconductor light emitting apparatus according to the third embodiment; and

FIG. 40 is a schematic partial enlarged cross-sectional view illustrating the method of manufacturing a semiconductor light emitting apparatus according to the third embodiment.

### DETAILED DESCRIPTION

Embodiments of the present disclosure will be described in detail with reference to the drawings. In the following drawings, the same or corresponding parts are denoted by the same reference numerals, and the description thereof will not be repeated. At least some of the components in the embodiments described below may be arbitrarily combined.

### First Embodiment

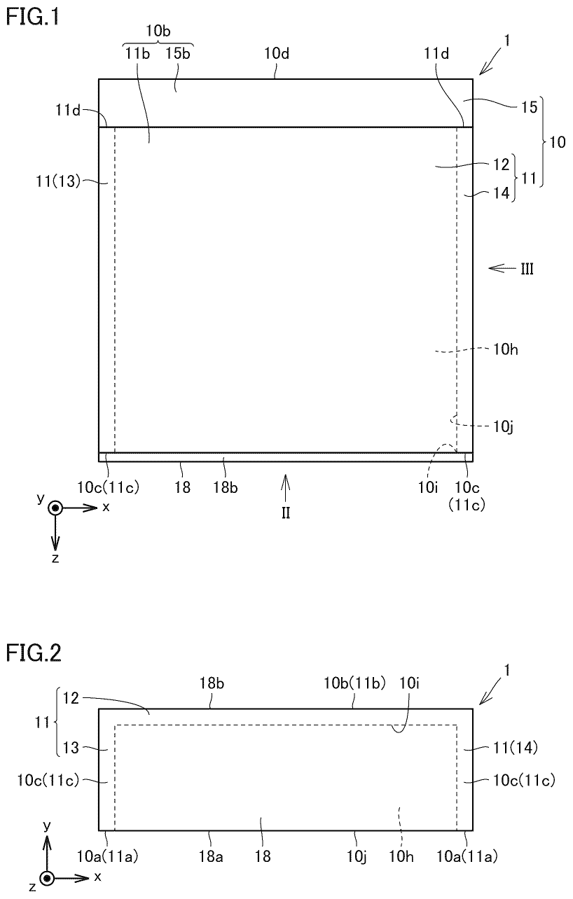

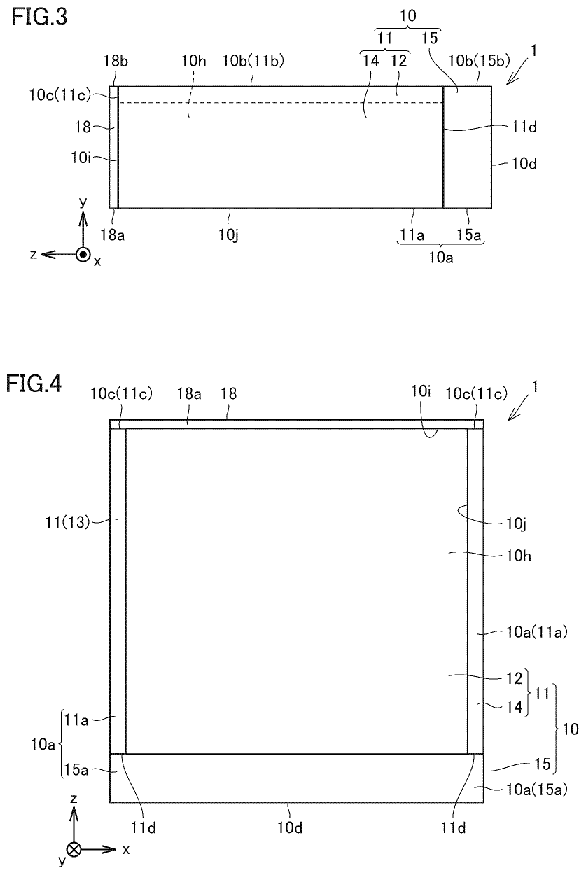

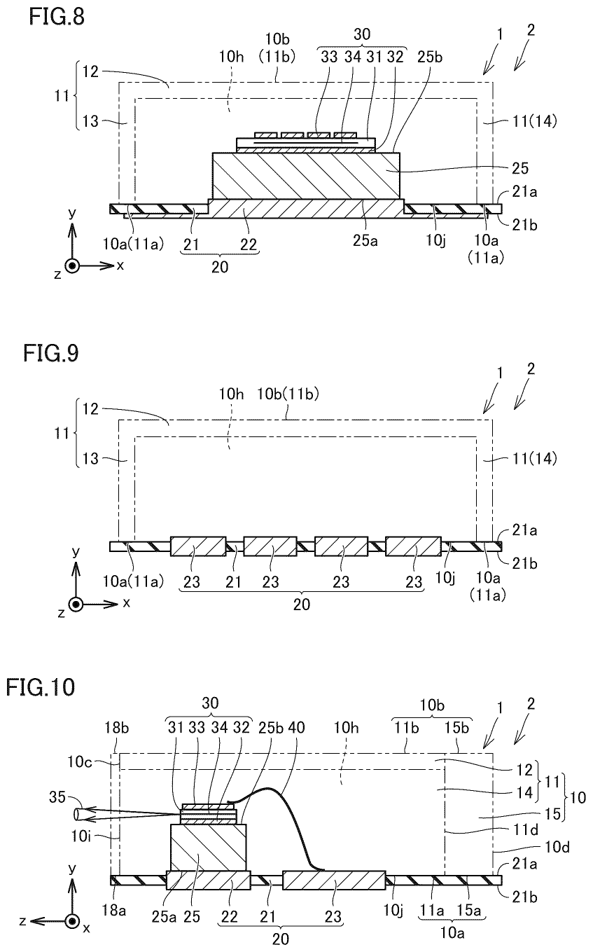

A protective case 1 according to a first embodiment will be described with reference to FIGS. 1 to 4. The protective case 1 protects a semiconductor light emitting device 30 (see FIGS. 5, 6, 8 and 10) from dust, moisture, and the like. The protective case 1 includes a protective cover 10 and a transparent plate 18.

The protective cover 10 may house the semiconductor light emitting device 30. The protective cover 10 is formed with a housing space 10h in which the semiconductor light emitting device 30 is housed.

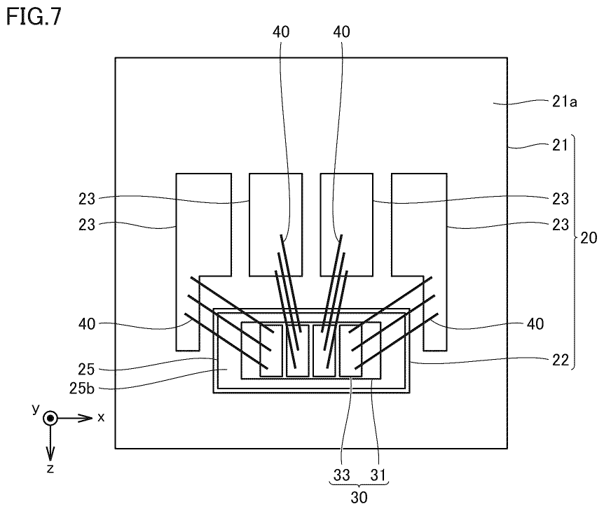

The protective cover 10 includes a first bottom surface 10a, a first top surface 10b opposite to the first bottom surface 10a, a front surface 10c, and a rear surface 10d opposite to the front surface 10c. The front surface 10c is connected to the first bottom surface 10a and the first top surface 10b. The rear surface 10d is connected to the first bottom surface 10a and the first top surface 10b. The first bottom surface 10a faces a base substrate 20 (see FIGS. 5 to 10) that supports the semiconductor light emitting device 30. The first bottom surface 10a is provided with an opening. The first bottom surface 10a is provided with a bottom opening 10j. The bottom opening 10j is communicated with the housing space 10h. The front surface 10c is provided with an opening. The front surface 10c is provided with a front opening 10i. The front opening 10i is communicated with the housing space 10h. A light beam 35 (see FIG. 10) emitted from the semiconductor light emitting device 30 passes through the front opening 10i. The front opening 10i extends to the first bottom surface 10a. The front opening 10i is communicated with the bottom opening 10j.

The protective cover 10 includes a cover body 11 and a rear wall 15.

The cover body 11 includes a bottom surface 11a, a top surface 11b opposite to the bottom surface 11a, a front surface 11c, and a rear surface 11d opposite to the front surface 11c. The front surface 11c is connected to the bottom surface 11a and the top surface 11b. The rear surface 11d is connected to the bottom surface 11a and the top surface 11b. The bottom surface 11a is provided with an opening. The opening provided in the bottom surface 11a is a bottom opening 10j. The front surface 11c is provided with an opening. The opening provided in the front surface 11c is the front opening 10i. The rear surface 11d is provided with an opening.

The cover body 11 includes a top plate 12 and side plates 13 and 14. The side plates 13 and 14 are connected to the top plate 12, and face each other. The side plates 13 and 14 include the bottom surface 11a of the cover body 11. The top plate 12 includes the top surface 11b of the cover body 11.

The rear wall 15 is connected to the cover body 11. The rear wall 15 is connected to the top plate 12 and the side plates 13 and 14. The rear wall 15 is connected to the rear surface 11d of the cover body 11. The rear wall 15 closes the opening provided in the rear surface 11d of the cover body 11. The rear wall 15 includes a bottom surface 15a and a top surface 15b opposite to the bottom surface 15a.

The first bottom surface 10a of the protective cover 10 includes the bottom surface 11a of the cover body 11 and the bottom surface 15a of the rear wall 15. The first top surface 10b of the protective cover 10 includes the top surface 11b of the cover body 11 and the top surface 15b of the rear wall 15. The cover body 11 includes the front surface 10c of the protective cover 10. The front surface 10c of the protective cover 10 is the front surface 11c of the cover body 11. The rear wall 15 includes the rear surface 10d of the protective cover 10. The rear surface 10d of the protective cover 10 is the rear surface of the rear wall 15. The bottom opening 10j is defined by the cover body 11 and the rear wall 15. Specifically, the bottom opening 10j is defined by the side plates 13 and 14 and the rear wall 15. The front opening 10i is defined by the cover body 11. Specifically, the front opening 10i is defined by the top plate 12 and the side plates 13 and 14. The front opening 10i extends to the bottom surface 11a of the cover body 11.

In the present embodiment, the cover body 11 is an integrally molded single member. The top plate 12 and the side plates 13 and 14 are integrally molded. The rear wall 15 is a separate member from the cover body 11. The cover body 11 is made of glass, resin, metal, or ceramic. The rear wall 15 is made of glass, resin, metal, or ceramic. The rear wall 15 may be made of the same material as the cover body 11, or may be made of a different material from the cover body 11.

The transparent plate 18 is attached to the front surface 10c of the protective cover 10. The transparent plate 18 is bonded to the front surface 10c of the protective cover 10 using a bonding member (not shown) such as an adhesive, a brazing material, solder, or a eutectic bonding metal. The transparent plate 18 closes the front opening 10i. The transparent plate 18 has a higher transmittance than the protective cover 10 with respect to the light beam 35 (see FIG. 10) emitted from the semiconductor light emitting device 30, and transmits the light beam 35 emitted from the semiconductor light emitting device 30. The transparent plate 18 is made of, for example, glass or a transparent resin. The transparent plate 18 includes a second bottom surface 18a and a second top surface 18b opposite to the second bottom surface 18a. The second bottom surface 18a faces the base substrate 20 (see FIGS. 5 to 10) that supports the semiconductor light emitting device 30.

The first bottom surface 10a of the protective cover 10 and the second bottom surface 18a of the transparent plate 18 are flush with each other. A level difference between the first top surface 10b of the protective cover 10 and the second top surface 18b of the transparent plate 18 is 20 μm or less. The first top surface 10b of the protective cover 10 and the second top surface 18b of the transparent plate 18 may be flush with each other. The bottom surface 11a of the cover body 11 and the bottom surface 15a of the rear wall 15 are flush with each other. A level difference between the top surface 11b of the cover body 11 and the top surface 15b of the rear wall 15 is 20 μm or less. The top surface 11b of the cover body 11 and the top surface 15b of the rear wall 15 may be flush with each other.

A semiconductor light emitting apparatus 2 according to the first embodiment will be described with reference to FIGS. 5 to 10. The semiconductor light emitting apparatus 2 mainly includes a protective case 1 of the present embodiment, a base substrate 20, a submount 25, a semiconductor light emitting device 30, and a conductive wire 40.

The base substrate 20 supports the semiconductor light emitting device 30. Specifically, the base substrate 20 supports the semiconductor light emitting device 30 with the submount 25 interposed therebetween.

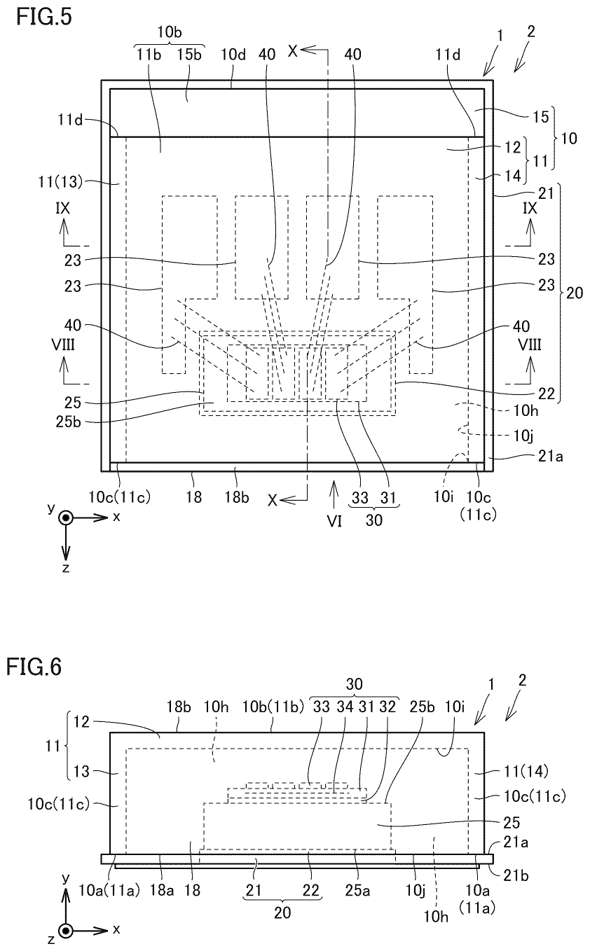

The base substrate 20 includes an insulating substrate 21, a first conductive member 23, and a second conductive member 22. The base substrate 20 is, for example, a printed circuit board (PCB). Specifically, the insulating substrate 21 includes a main surface 21a and a main surface 21b opposite to the main surface 21a. Although not particularly limited, the insulating substrate 21 is made of, for example, a glass epoxy resin. The second conductive member 22 is separated from the first conductive member 23, and is electrically insulated from the first conductive member 23. The first conductive member 23 and the second conductive member 22 are made of, for example, a metal such as copper (Cu). As illustrated in FIGS. 6 and 8 to 10, the first conductive member 23 and the second conductive member 22 protrude from the main surface 21a. The first conductive member 23 and the second conductive member 22 may further protrude from the main surface 21b. Therefore, the base substrate 20 may be surface-mounted on a mounting substrate (not shown).

With reference to FIGS. 5 to 8 and 10, the submount 25 is mounted on the second conductive member 22. The submount 25 includes a main surface 25a facing the second conductive member 22, and a main surface 25b opposite to the main surface 25a and facing the semiconductor light emitting device 30. The main surface 25a of the submount 25 is bonded to the second conductive member 22 using a conductive bonding member (not shown) such as solder. The main surface 25a and the main surface 25b are separated from each other in the thickness direction of the submount 25. The thickness of the submount 25, which is the distance between the main surface 25a and the main surface 25b, is 100 μm or more. The thickness of the submount 25 may be 200 μm or more, 300 μm or more, or 400 μm or more.

The submount 25 electrically connects the second conductive member 22 and the second electrode 32 of the semiconductor light emitting device 30 to each other. In the present embodiment, the submount 25 is a lead frame. Therefore, the cost of the submount 25 is reduced. The lead frame is made of, for example, a metal such as copper (Cu). The submount 25 is not limited to a lead frame as long as it is electrically conductive in the thickness direction of the submount 25. The submount 25 may include an insulating member (not shown) such as a glass epoxy substrate, an aluminum nitride substrate or an alumina substrate, a conductive via (not shown), and a conductive pattern (not shown) connected to the conductive via. The conductive via is embedded in the insulating member and extends in the thickness direction of the insulating member.

With reference to FIGS. 5 to 8 and 10, the semiconductor light emitting device 30 is mounted on the submount 25. The semiconductor light emitting device 30 includes a semiconductor main body 31, a first electrode 33, and a second electrode 32. The second electrode 32 of the semiconductor light emitting device 30 is bonded to the main surface 25b of the submount 25 using a conductive bonding member (not shown) such as solder. The semiconductor main body 31 is made of a semiconductor material such as AlGaAs, InAlGaP, or InAlGaN. The semiconductor main body 31 includes a light emitting layer 34, an n-type cladding layer (not shown), and a p-type cladding layer (not shown). The light emitting layer 34 is disposed between the n-type cladding layer and the p-type cladding layer. When a current is supplied to the light emitting layer 34 from the first electrode 33 or the second electrode 32, a light beam is emitted from the light emitting layer 34. In the present embodiment, the semiconductor light emitting device 30 is a laser diode, and the light beam 35 emitted from the light emitting layer 34 is a laser beam.

The semiconductor main body 31 includes a first surface facing the submount 25 and a second surface opposite to the first surface. The first electrode 33 and the second electrode 32 are provided on the semiconductor main body 31. The first electrode 33 is farther from the submount 25 than the second electrode 32. For example, the first electrode 33 is provided on the second surface, and the second electrode 32 is provided on the first surface. In the present embodiment, the first electrode 33 is an anode electrode, and the second electrode 32 is a cathode electrode.

With reference to FIGS. 5, 7 and 10, the conductive wire 40 is connected to the first electrode 33 of the semiconductor light emitting device 30 and the first conductive member 23. For example, the conductive wire 40 is bonded to the first electrode 33 and the first conductive member 23. The conductive wire 40 is made of, for example, a metal such as gold (Au), copper (Cu), or aluminum (Al).

With reference to FIGS. 5, 6 and 8 to 10, the protective case 1 is attached to the base substrate 20 (more specifically, the main surface 21a of the insulating substrate 21). The protective case 1 is fixed to the base substrate 20 (more specifically, the main surface 21a of the insulating substrate 21) using a bonding member (not shown) such as an adhesive, a brazing material, or solder. The first bottom surface 10a of the protective cover 10 faces the main surface 21a of the insulating substrate 21. The top plate 12 faces the main surface 25b of the submount 25 and the main surface 21a of the insulating substrate 21. The first bottom surface 10a of the protective cover 10 and the second bottom surface 18a of the transparent plate 18 are flush with each other. Therefore, the first bottom surface 10a of the protective cover 10 and the second bottom surface 18a of the transparent plate 18 can be in close contact with the base substrate 20 (more specifically, the main surface 21a of the insulating substrate 21). The light beam 35 emitted from the semiconductor light emitting device 30 passes through the front opening 10i. The semiconductor light emitting apparatus 2 is a side emission type semiconductor light emitting apparatus.

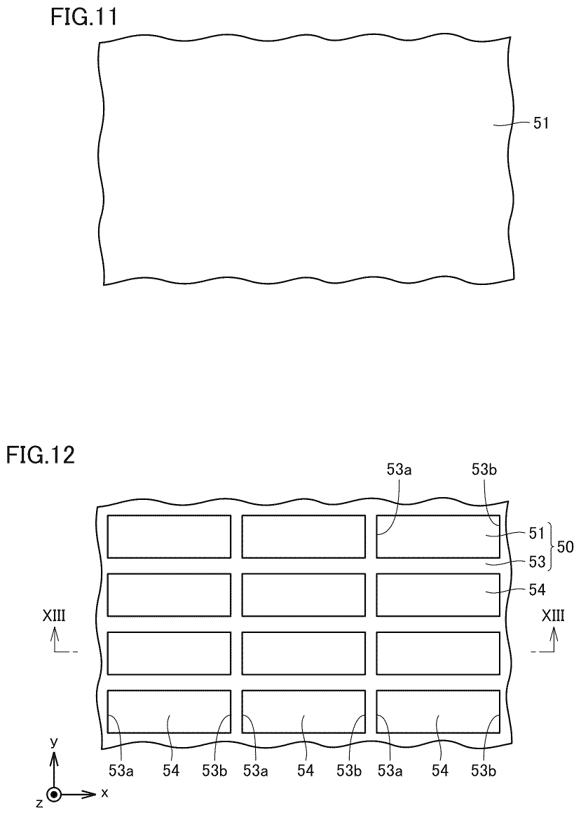

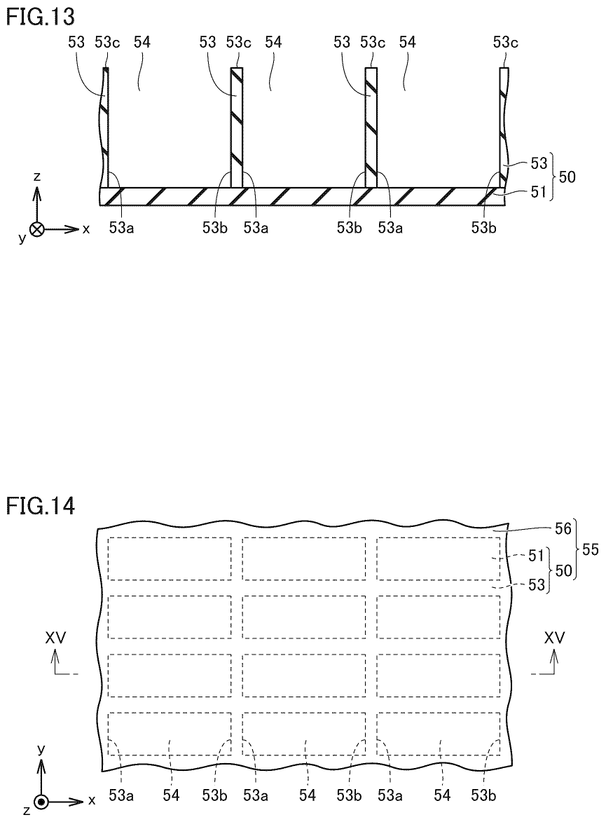

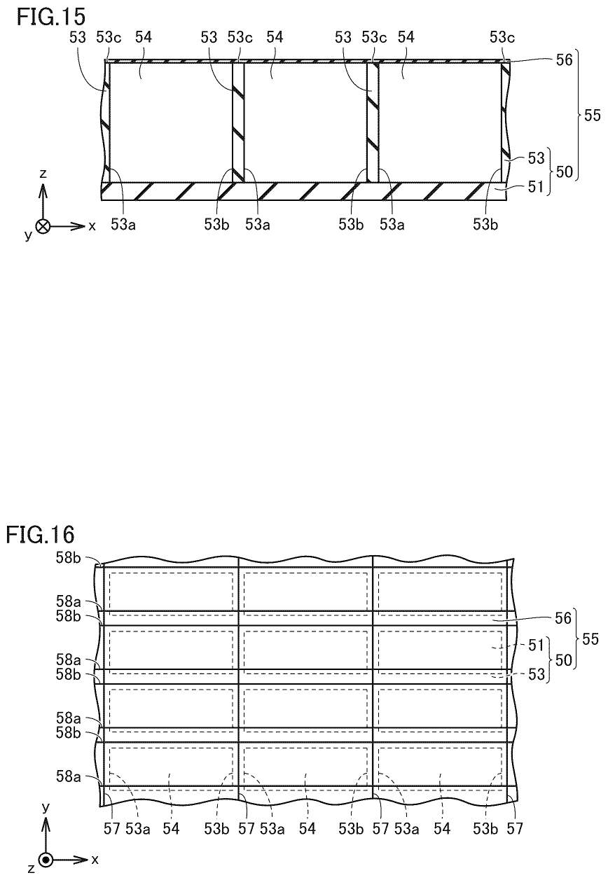

A method of manufacturing the protective case 1 according to the present embodiment will be described with reference to FIGS. 11 to 16. The method of manufacturing the protective case 1 according to the present embodiment includes a step of forming a protective cover array 50 (see FIGS. 11 to 13), a step of attaching a transparent member 56 to a surface 53c of a hollow member 53 (see FIGS. 14 and 15), and a step of dicing a stack 55 (see FIG. 16).

Specifically, as illustrated in FIG. 11, a base member 51 is prepared. The base member 51 is made of the same material as the rear wall 15. The size of the base member 51 is larger than the size of the rear wall 15.

Then, as illustrated in FIGS. 12 and 13, a hollow member 53 is formed on the base member 51. Specifically, a mold (not shown) is installed on the base member 51. A cavity in the mold is filled with a molten or softened material (for example, resin or glass). The material is cured. Thus, the hollow member 53 is formed on the base member 51. Thus, a protective cover array 50 that includes the base member 51 and the hollow member 53 is formed.

The hollow member 53 includes a surface 53c opposite to the base member 51. The surface 53c of the hollow member 53 is provided with a plurality of holes 54. The plurality of holes 54 are arranged along a first direction and a second direction different from the first direction in a plan view of the surface 53c of the hollow member 53. For example, the first direction is the x direction, and the second direction is the y direction perpendicular to the first direction. The base member 51 is exposed from the hollow member 53 in each of the plurality of holes 54. The hollow member 53 includes a first edge 53a and a second edge 53b that define each of the plurality of holes 54. The second edge 53b is opposed to the first edge 53a. The first edge 53a and the second edge 53b are separated from each other in the first direction of the first direction and the second direction along which the plurality of holes 54 are arranged.

As illustrated in FIGS. 14 and 15, a transparent member 56 is attached to the surface 53c of the hollow member 53. The transparent member 56 is made of the same material as the transparent plate 18. The size of the transparent member 56 is larger than the size of the transparent plate 18. The transparent member 56 is bonded to the surface 53c of the hollow member 53 using a bonding member (not shown) such as an adhesive, a brazing material, or solder. The plurality of holes 54 of the hollow member 53 are closed by the transparent member 56. Thus, a stack 55 that includes the protective cover array 50 and the transparent member 56 is formed.

As illustrated in FIG. 16, the stack 55 is cut along cutting planes 57, 58a and 58b using a dicing blade (not shown) or the like. The stack 55 is diced. By dicing the stack 55, the base member 51 is cut to form the rear wall 15, the hollow member 53 is cut to form the cover body 11, and the transparent member 56 is cut to form the transparent plate 18. Thus, the protective case 1 is obtained.

In a plan view of the surface 53c of the hollow member 53, the cutting plane 57 extends along the second direction (for example, the y direction) of the first direction (for example, the x direction) and the second direction (for example, the y direction) along which the plurality of holes 54 are arranged. The first direction is, for example, the longitudinal direction of the hole 54. The second direction is, for example, the lateral direction of the hole 54.

In a plan view of the surface 53c of the hollow member 53, the cutting planes 58a and 58b extend along the first direction (for example, the x direction) of the first direction (for example, the x direction) and the second direction (for example, the y direction) along which the plurality of holes 54 are arranged. In a plan view of the surface 53c of the hollow member 53, the cutting plane 58a intersects the first edge 53a and the second edge 53b, and passes through an inside of each of the plurality of holes 54. The cutting plane 58a may be shifted to one side (the −y direction in the present embodiment) relative to the center of the first edge 53a and the center of the second edge 53b. Therefore, the cutting plane 58a is located near a non-formation region of the hole 54 in the hollow member 53. By cutting the hollow member 53 along the cutting plane 58a, burrs can be prevented from being formed in the transparent plate 18. In a plan view of the surface 53c of the hollow member 53, the cutting plane 58b does not intersect the first edge 53a and the second edge 53b, and is located in the hollow member 53 between two adjacent holes 54.

The stack 55 may be firstly cut along the cutting plane 57 and then cut along the cutting planes 58a, 58b. The stack 55 may be firstly cut along the cutting planes 58a, 58b and then cut along the cutting plane 57.

The first bottom surface 10a of the protective cover 10 and the second bottom surface 18a of the transparent plate 18 are a part of the cutting plane 58a. Therefore, the first bottom surface 10a and the second bottom surface 18a are cutting planes. The protective cover 10 and the transparent plate 18 are cut together along the cutting plane 58a. Therefore, a cutting scratch that continuously extends across the first bottom surface 10a and the second bottom surface 18a is formed on the first bottom surface 10a and the second bottom surface 18a. The bottom surface 11a of the cover body 11 and the bottom surface 15a of the rear wall 15 are a part of the cutting plane 58a. Therefore, the bottom surface 11a and the bottom surface 15a are cutting planes. The cover body 11 and the rear wall 15 are cut together along the cutting plane 58a. Therefore, a cutting scratch that continuously extends across the bottom surface 11a and the bottom surface 15a is formed on the bottom surface 11a and the bottom surface 15a. According to the simple and low-cost method of cutting the stack 55 along the cutting plane 58a, the first bottom surface 10a of the protective cover 10 and the second bottom surface 18a of the transparent plate 18 are flush with each other, and the bottom surface 11a of the cover body 11 and the bottom surface 15a of the rear wall 15 are flush with each other.

The first top surface 10b of the protective cover 10 and the second top surface 18b of the transparent plate 18 are a part of the cutting plane 58b. Therefore, the first top surface 10b and the second top surface 18b are cutting planes. The protective cover 10 and the transparent plate 18 are cut together along the cutting plane 58b. Therefore, a cutting scratch that continuously extends across the first top surface 10b and the second top surface 18b is formed on the first top surface 10b and the second top surface 18b. The top surface 11b of the cover body 11 and the top surface 15b of the rear wall 15 are a part of the cutting plane 58b. Therefore, the top surface 11b and the top surface 15b are cutting planes. The cover body 11 and the rear wall 15 are cut together along the cutting plane 58b. Therefore, a cutting scratch that continuously extends across the top surface 11b and the top surface 15b is formed on the top surface 11b and the top surface 15b. According to the simple and low-cost method of cutting the stack 55 along the cutting plane 58b, the first top surface 10b of the protective cover 10 and the second top surface 18b of the transparent plate 18 are flush with each other, and the top surface 11b of the cover body 11 and the top surface 15b of the rear wall 15 are flush with each other.

The operation of the semiconductor light emitting apparatus 2 according to the present embodiment will be described. A high-frequency pulse current signal is supplied from a drive circuit (not shown) to the first conductive member 23. The high-frequency pulse current signal is supplied to the semiconductor light emitting device 30 through the first conductive member 23 and the conductive wire 40. In accordance with the high-frequency pulse current signal, the semiconductor light emitting device 30 emits a light beam 35.

The semiconductor light emitting device 30 is mounted on the submount 25. Therefore, the light emitting layer 34 of the semiconductor light emitting device 30 can be disposed farther from the base substrate 20. Thus, it is possible to prevent a part of the light beam 35 emitted from the semiconductor light emitting device 30 from being blocked by the base substrate 20 or a mounting substrate (not shown) on which the base substrate 20 is mounted.

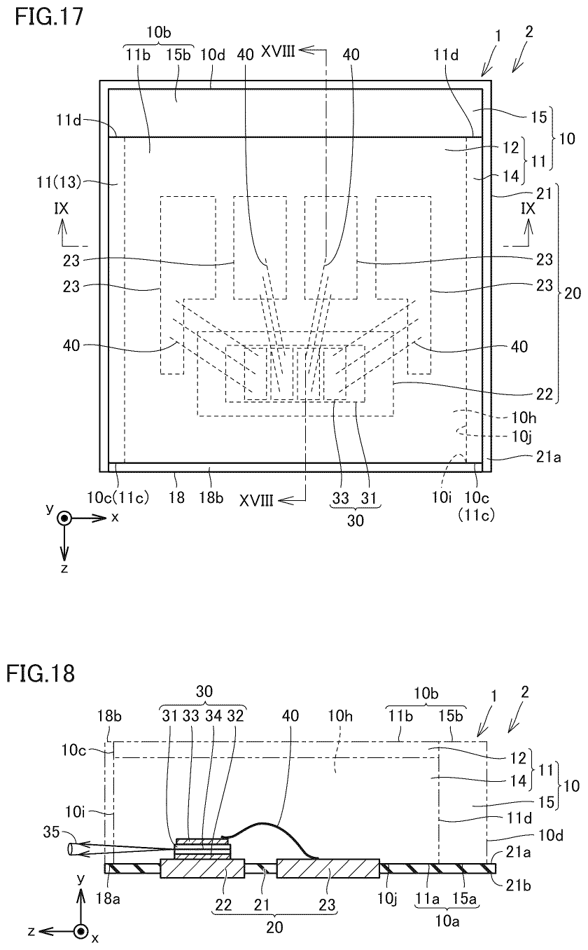

As illustrated in FIGS. 17 and 18, if a part of the light beam 35 emitted from the semiconductor light emitting device 30 is not blocked by the base substrate 20 or a mounting substrate (not illustrated) on which the base substrate 20 is mounted, the submount 25 may be omitted and the semiconductor light emitting device 30 may be mounted on the second conductive member 22. The second electrode 32 of the semiconductor light emitting device 30 may be bonded to the second conductive member 22 using a conductive bonding member (not shown) such as solder.

The effects of the protective case for a semiconductor light emitting device (the protective case 1), the method of manufacturing the same, and the semiconductor light emitting apparatus 2 according to the present embodiment will be described.

The protective case for a semiconductor light emitting device (the protective case 1) of the present embodiment includes a protective cover 10 in which the semiconductor light emitting device 30 can be housed, and a transparent plate 18. The protective cover 10 includes a first bottom surface 10a, a first top surface 10b opposite to the first bottom surface 10a, a front surface 10c connected to the first bottom surface 10a and the first top surface 10b, and a rear surface 10d opposite to the front surface 10c and connected to the first bottom surface 10a and the first top surface 10b. The first bottom surface 10a of the protective cover 10 faces a base substrate 20 that supports the semiconductor light emitting device 30. The first bottom surface 10a of the protective cover 10 is provided with a bottom opening 10j. The front surface 10c of the protective cover 10 is provided with a front opening 10i that allows a light beam 35 emitted from the semiconductor light emitting device 30 to pass therethrough. The front opening 10i of the protective cover 10 extends to the first bottom surface 10a of the protective cover 10. The transparent plate 18 is attached to the front surface 10c of the protective cover 10 to close the front opening 10i. The transparent plate 18 includes a second bottom surface 18a that faces the base substrate 20. The first bottom surface 10a of the protective cover 10 and the second bottom surface 18a of the transparent plate 18 are flush with each other.

Since the first bottom surface 10a of the protective cover 10 and the second bottom surface 18a of the transparent plate 18 are flush with each other, when the protective case 1 is attached to the base substrate 20, the adhesion between the protective case 1 and the base substrate 20 that supports the semiconductor light emitting device 30 is improved. This improves the airtightness of the housing space 10h of the protective case 1 in which the semiconductor light emitting device 30 is housed. Thus, it is possible to prevent dust and moisture outside the protection cover 10 from entering the housing space 10h. Further, it is possible to increase the bonding strength between the protective case 1 and the base substrate 20 when bonding the protective case 1 to the base substrate 20 using a bonding member (not shown) such as an adhesive, a brazing material, or solder.

Furthermore, since the first bottom surface 10a of the protective cover 10 and the second bottom surface 18a of the transparent plate 18 are flush with each other, it is possible to collectively form the first bottom surface 10a of the protective cover 10 and the second bottom surface 18a of the transparent plate 18 in the cutting step (see FIG. 16). Thus, it is possible to reduce the manufacturing cost of the protective case 1.

In the protective case for a semiconductor light emitting device (the protective case 1) of the present embodiment, the transparent plate 18 includes a second top surface 18b opposite to the second bottom surface 18a. The level difference between the first top surface 10b of the protective cover 10 and the second top surface 18b of the transparent plate 18 is 20 μm or less.

Therefore, when the protective case 1 is transported using a transport device such as a suction hand, the protective case 1 can be more reliably lifted and transported by the transport device. Thus, it is possible to reduce the manufacturing cost of the protective case 1.

In the protective case for a semiconductor light emitting device (the protective case 1) of the present embodiment, the transparent plate 18 includes a second top surface 18b opposite to the second bottom surface 18a. The first top surface 10b of the protective cover 10 and the second top surface 18b of the transparent plate 18 are flush with each other.

Therefore, when the protective case 1 is transported using a transport device such as a suction hand, the protective case 1 can be more reliably lifted and transported by the transport device. Thus, it is possible to reduce the manufacturing cost of the protective case 1.

In the protective case for a semiconductor light emitting device (the protective case 1) of the present embodiment, the protective cover 10 includes a cover body 11 that includes a front surface 10c, and a rear wall 15 that includes a rear surface 10d and is connected to the cover body 11. The cover body 11 is provided with the bottom opening 10j and the front opening 10i. The rear wall 15 is a separate member from the cover body 11.

Therefore, it is possible to optimize the material of the cover body 11 and the material of the rear wall 15 from the viewpoint of the cost of the protective case 1 or the bonding strength between the protective case 1 and the base substrate 20. It is possible to reduce the cost of the protective case 1, or it is possible to increase the bonding strength between the protective case 1 and the base substrate 20.

In the protective case for a semiconductor light emitting device (the protective case 1) of the present embodiment, the cover body 11 is made of glass, resin, metal, or ceramic. The rear wall 15 is made of glass, resin, metal, or ceramic.

Therefore, it is possible to reduce the cost of the protective case 1.

The method of manufacturing the protective case for a semiconductor light emitting device (the protective case 1) of the present embodiment includes a step of forming a protective cover array 50. The protective cover array 50 includes a base member 51 and a hollow member 53 formed on the base member 51. The hollow member 53 includes a surface 53c opposite to the base member 51. The surface 53c of the hollow member 53 is provided with a plurality of holes 54. The base member 51 is exposed from the hollow member 53 in each of the plurality of holes 54. The hollow member 53 includes a first edge 53a and a second edge 53b that define each of the plurality of holes 54. The second edge 53b is opposed to the first edge 53a. The method of manufacturing the protective case for a semiconductor light emitting device (the protective case 1) includes a step of attaching the transparent plate 18 to the surface 53c of the hollow member 53 to form a stack 55 that includes the protective cover array 50 and the transparent plate 18. The plurality of holes 54 are closed by the transparent plate 18. The method of manufacturing the protective case for a semiconductor light emitting device (the protective case 1) includes a step of dicing the stack 55 by cutting the stack 55 along the cutting plane 58a. In a plan view of the surface 53c of the hollow member 53, the cutting plane 58a intersects the first edge 53a and the second edge 53b and passes through an inside of each of the plurality of holes 54.

Therefore, the first bottom surface 10a of the protective cover 10 and the second bottom surface 18a of the transparent plate 18 are flush with each other. When the protective case 1 is attached to the base substrate 20, the adhesion between the protective case 1 and the base substrate 20 that supports the semiconductor light emitting device 30 is improved. This improves the airtightness of the housing space 10h of the protective case 1 in which the semiconductor light emitting device 30 is housed. Thus, it is possible to prevent dust and moisture outside the protection cover 10 from entering the housing space 10h. Further, it is possible to increase the bonding strength between the protective case 1 and the base substrate 20 when bonding the protective case 1 to the base substrate 20 using a bonding member (not shown) such as an adhesive, a brazing material, or solder.

Furthermore, since the first bottom surface 10a of the protective cover 10 and the second bottom surface 18a of the transparent plate 18 are flush with each other, it is possible to collectively form the first bottom surface 10a of the protective cover 10 and the second bottom surface 18a of the transparent plate 18 in the step of cutting the stack 55 along the cutting plane 58a (see FIG. 16). Thus, it is possible to reduce the cost of the protective case 1.

In the method of manufacturing the protective case for a semiconductor light emitting device (the protective case 1) of the present embodiment, the step of forming the protective cover array 50 includes a step of preparing the base member 51 and a step of forming the hollow member 53 on the base member 51.

Therefore, it is possible to optimize the material of the cover body 11 (the hollow member 53) and the material of the rear wall (the base member 51) from the viewpoint of the cost of the protective case 1 or the bonding strength between the protective case 1 and the base substrate 20. It is possible to reduce the cost of the protective case 1, or it is possible to increase the bonding strength between the protective case 1 and the base substrate 20.

The semiconductor light emitting apparatus 2 of the present embodiment includes a protective case 1 of the present embodiment, a semiconductor light emitting device 30, and a base substrate 20 that supports the semiconductor light emitting device 30.

Since the first bottom surface 10a of the protective cover 10 and the second bottom surface 18a of the transparent plate 18 are flush with each other, when the protective case 1 is attached to the base substrate 20, the adhesion between the protective case 1 and the base substrate 20 that supports the semiconductor light emitting device 30 is improved. This improves the airtightness of the housing space 10h of the protective case 1 in which the semiconductor light emitting device 30 is housed. Thus, it is possible to prevent dust and moisture outside the protection cover 10 from entering the housing space 10h. Further, it is possible to increase the bonding strength between the protective case 1 and the base substrate 20 when bonding the protective case 1 to the base substrate 20 using a bonding member (not shown) such as an adhesive, a brazing material, or solder.

Furthermore, since the first bottom surface 10a of the protective cover 10 and the second bottom surface 18a of the transparent plate 18 are flush with each other, it is possible to collectively form the first bottom surface 10a of the protective cover 10 and the second bottom surface 18a of the transparent plate 18 in the cutting step (see FIG. 16). Thus, it is possible to reduce the cost of the protective case 1, which makes it possible to reduce the cost of the semiconductor light emitting apparatus 2.

### Second Embodiment

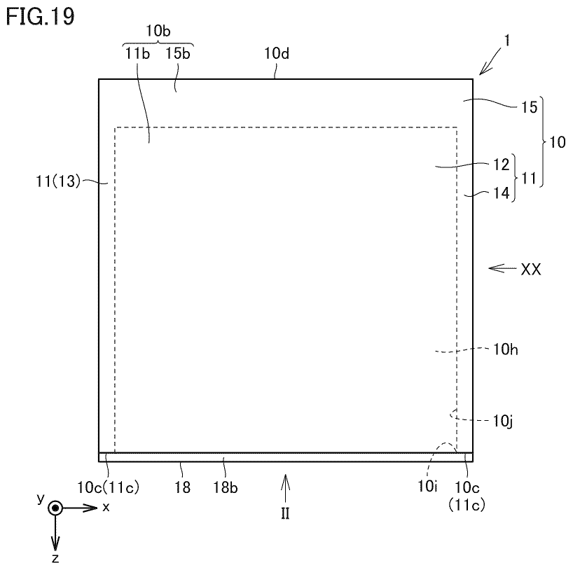

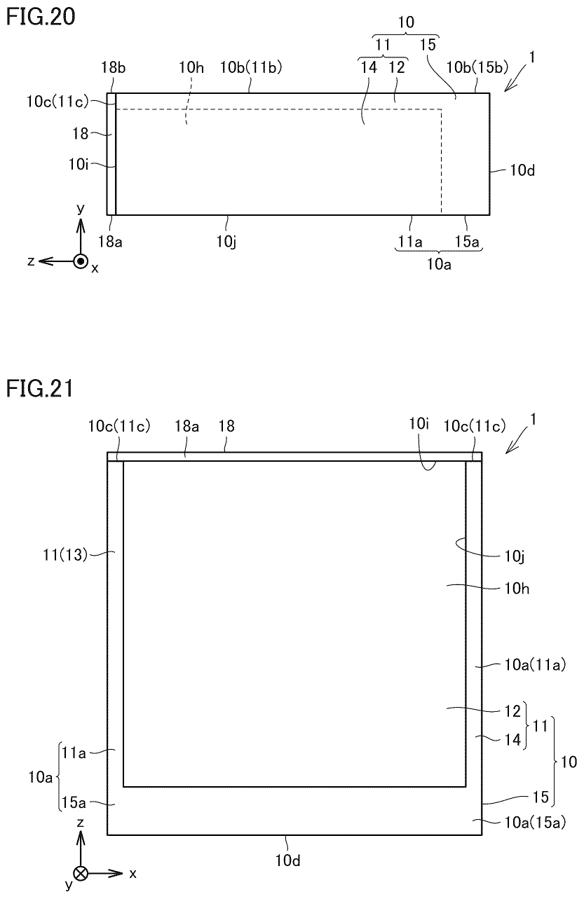

A protective case 1 according to a second embodiment will be described with reference to FIGS. 2 and 19 to 21. The protective case 1 of the present embodiment has the same configuration as the protective case 1 of the first embodiment, but is different from the protective case 1 of the first embodiment mainly in the following points. In the present embodiment, the cover body 11 and the rear wall 15 are integrally molded as a single member. The cover body 11 and the rear wall 15 are made of the same material. The cover body 11 and the rear wall 15 are made of, for example, glass, resin, metal, or ceramic.

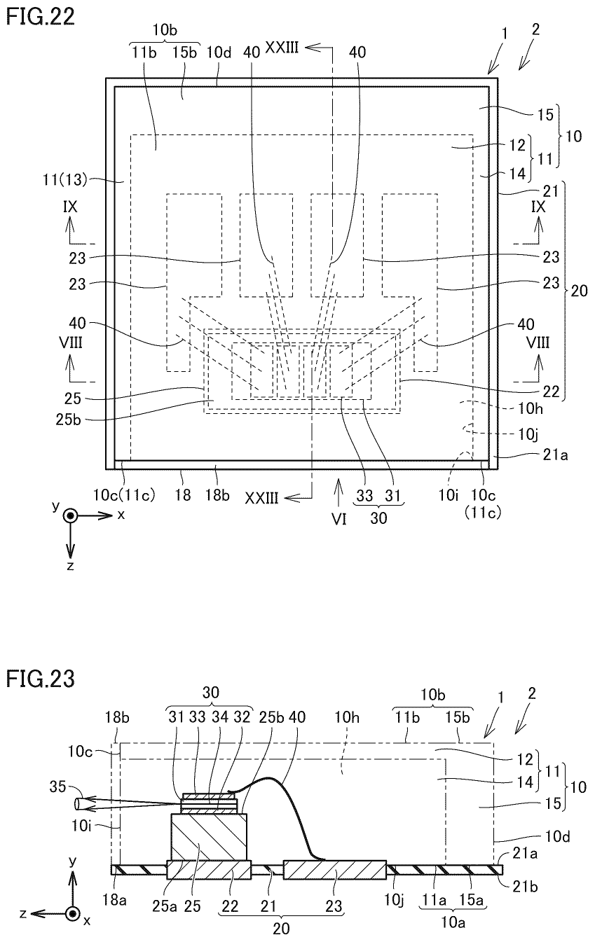

A semiconductor light emitting apparatus 2 according to the second embodiment will be described with reference to FIGS. 6 to 9, 22 and 23. The semiconductor light emitting apparatus 2 of the present embodiment has the same configuration as the semiconductor light emitting apparatus 2 of the first embodiment, but is different from the semiconductor light emitting apparatus 2 of the first embodiment mainly in the following points. The semiconductor light emitting apparatus 2 of the present embodiment includes the protective case 1 of the present embodiment instead of the protective case 1 of the first embodiment.

A method of manufacturing the protective case 1 according to the present embodiment will be described with reference to FIGS. 16 and 24 to 27. The method of manufacturing the protective case 1 according to the present embodiment includes the same steps as those of the method of manufacturing the protective case 1 according to the first embodiment, but is different from the method of manufacturing the protective case 1 according to the present embodiment mainly in the following points.

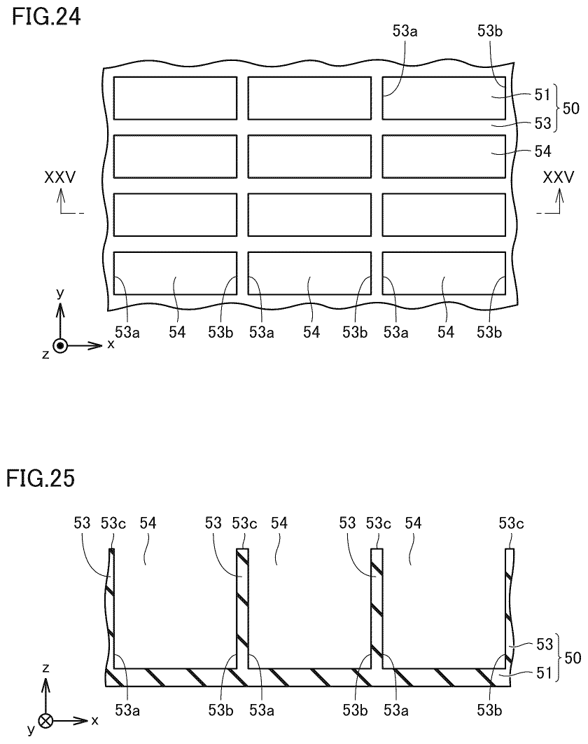

With reference to FIGS. 24 and 25, in the method of manufacturing protective case 1 of the present embodiment, the step of forming the protective cover array 50 includes integrally molding a base member 51 and a hollow member 53. Specifically, a cavity in the mold is filled with a molten or softened material (for example, resin or glass). The material is cured. The base member 51 and the hollow member 53 are integrally molded to form a protective cover array 50.

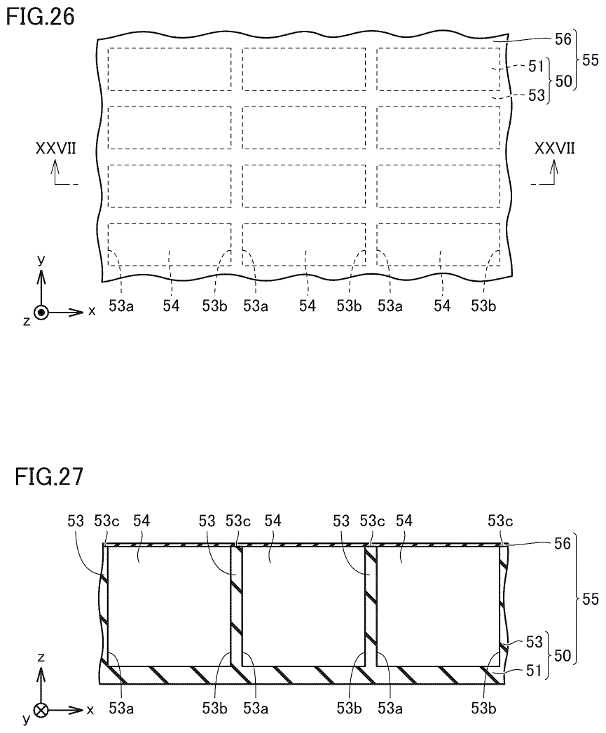

With reference to FIGS. 26 and 27, similar to the first embodiment (see FIGS. 14 and 15), a transparent member 56 is attached to the surface 53c of hollow member 53 to form a stack 55 that includes the protective cover array 50 and the transparent member 56. Then, as illustrated in FIG. 16, the stack 55 is diced in the same manner as in the first embodiment (see FIG. 16). Thus, the protective case 1 of the present embodiment is obtained.

The protective case for a semiconductor light emitting device (the protective case 1), the method of manufacturing the same, and the semiconductor light emitting apparatus 2 according to the present embodiment have the following effects in addition to the effects of the protective case for a semiconductor light emitting device (the protective case 1), the method of manufacturing the same, and the semiconductor light emitting apparatus 2 according to the first embodiment.

In the protective case for a semiconductor light emitting device (the protective case 1) of the present embodiment, the protective cover 10 includes a cover body 11 that includes a front surface 10c, and a rear wall 15 that includes a rear surface 10d and is connected to the cover body 11. The cover body 11 is provided with a bottom opening 10j and a front opening 10i. The rear wall 15 and the cover body 11 are integrally molded as a single member.

Since the rear wall 15 and the cover body 11 are integrally molded, it is possible to further reduce the cost of the protective case 1.

In the method of manufacturing the protective case for a semiconductor light emitting device (the protective case 1) of the present embodiment, the step of forming the protective cover array 50 includes integrally molding the base member 51 and the hollow member 53.

Since the base member 51 and the hollow member 53 are integrally molded, it is possible to further reduce the cost of the protective case 1.

In the protective case for a semiconductor light emitting device (the protective case 1) of the present embodiment, the cover body 11 and the rear wall 15 are made of glass, resin, metal, or ceramic.

Therefore, it is possible to reduce the cost of the protective case 1.

The semiconductor light emitting apparatus 2 of the present embodiment includes a protective case 1 of the present embodiment, a semiconductor light emitting device 30, and a base substrate 20 that supports the semiconductor light emitting device 30.

Since the first bottom surface 10a of the protective cover 10 and the second bottom surface 18a of the transparent plate 18 are flush with each other, when the protective case 1 is attached to the base substrate 20, the adhesion between the protective case 1 and the base substrate 20 that supports the semiconductor light emitting device 30 is improved. This improves the airtightness of the housing space 10h of the protective case 1 in which the semiconductor light emitting device 30 is housed. Thus, it is possible to prevent dust and moisture outside the protection cover 10 from entering the housing space 10h. Further, it is possible to increase the bonding strength between the protective case 1 and the base substrate 20 when bonding the protective case 1 to the base substrate 20 using a bonding member (not shown) such as an adhesive, a brazing material, or solder.

Furthermore, since the first bottom surface 10a of the protective cover 10 and the second bottom surface 18a of the transparent plate 18 are flush with each other, it is possible to collectively form the first bottom surface 10a of the protective cover 10 and the second bottom surface 18a of the transparent plate 18 in the cutting step (see FIG. 16). The rear wall 15 and the cover body 11 are integrally molded. Thus, it is possible to reduce the cost of the protective case 1, which makes it possible to reduce the cost of the semiconductor light emitting apparatus 2.

### Third Embodiment

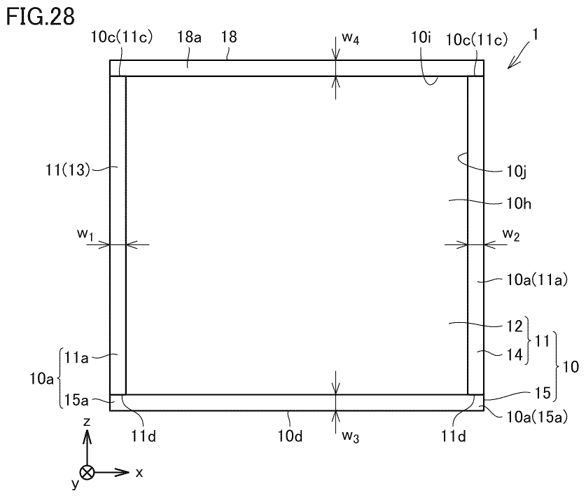

A protective case 1 according to a third embodiment will be described with reference to FIG. 28. The protective case 1 of the present embodiment has the same configuration as the protective case 1 of the first embodiment, but is different from the protective case 1 of the first embodiment mainly in the following points.

In the protective case 1 of the present embodiment, the width (w₁, w₂, w₃) of the first bottom surface 10a of the protective cover 10 around the bottom opening 10j is equal to the width w₄ of the second bottom surface 18a of the transparent plate 18. Specifically, each of the width w₁ of the bottom surface of the side plate 13, the width w₂ of the bottom surface of the side plate 14, and the width w₃ of the bottom surface 15a of the rear wall 15 is equal to the width w₄ of the second bottom surface 18a. In the present specification, the expression that the width wₐ is equal to the width w_{b} means that the difference between the width wₐ and the width w_{b} is 10% or less of the width w_{b}.

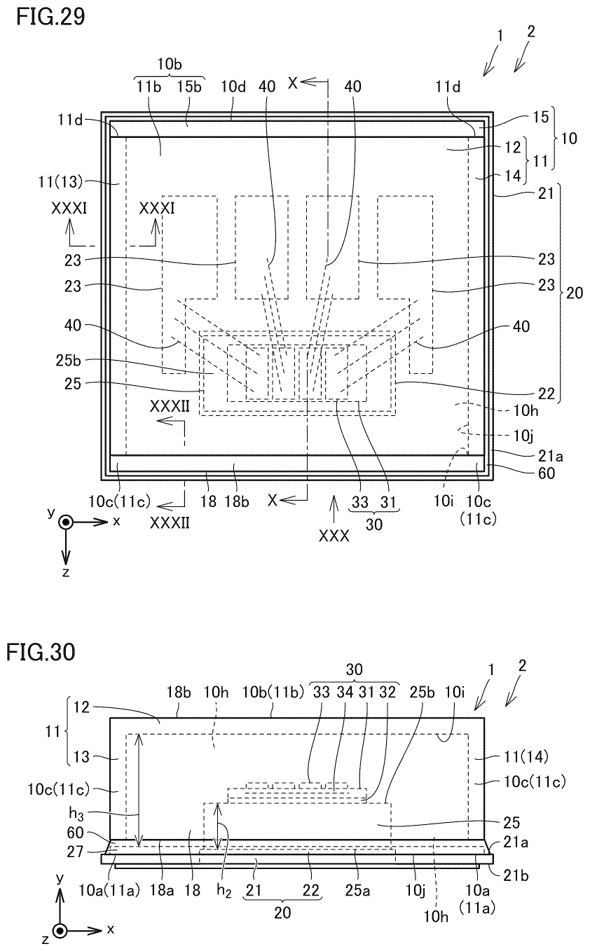

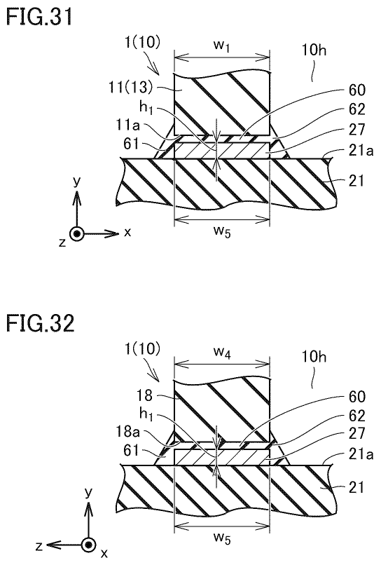

A semiconductor light emitting apparatus 2 according to a third embodiment will be described with reference to FIGS. 29 to 33. The semiconductor light emitting apparatus 2 of the present embodiment has the same configuration as the semiconductor light emitting apparatus 2 of the first embodiment, but is different from the semiconductor light emitting apparatus 2 of the first embodiment mainly in the following points.

The semiconductor light emitting apparatus 2 of the present embodiment further includes a projection 27 and a bonding member 60.

With reference to FIGS. 30 to 33, the projection 27 is provided on the base substrate 20 (specifically, the main surface 21a of the insulating substrate 21). Although the method of forming the projection 27 is not particularly limited, the projection 27 may be formed together with the first conductive member 23 and the second conductive member 22 by etching a copper plate provided on the main surface 21a of the insulating substrate 21, for example. The projection 27 may be integral with the base substrate 20 (specifically, the insulating substrate 21). In a plan view of the main surface 21a, the projection 27 surrounds the semiconductor light emitting device 30, and has a frame shape. In a plan view of the main surface 21a, the width w₅ of the projection 27 is constant over the entire circumference of the projection 27. In the present specification, the expression that the width w₅ of the projection 27 is constant means that the difference between the maximum value of the width of the projection 27 and the minimum value of the width of the projection 27 is 10% or less of the maximum value of the width of the projection 27.

The height h₁ of the projection 27 is, for example, 50% or less of the height h₂ of the submount 25. The height h₂ of the submount 25 is the thickness of the submount 25, i.e., the distance between the main surface 25a and the main surface 25b of the submount 25. The height h₁ of the projection 27 may be 40% or less of the height h₂ of the submount 25, or may be 30% or less of the height h₂ of the submount 25. The height h₁ of the projection 27 is, for example, 50% or less of the height h₃ of the front opening 10i. The height h₁ of the projection 27 may be 40% or less of the height h₃ of the front opening 10i, or may be 30% or less of the height h₃ of the front opening 10i. Since the height h₁ of the projection 27 is smaller than the height h₂ of the submount 25 and the height h₃ of the front opening 10i, it is possible to prevent a part of the light beam 35 emitted from the semiconductor light emitting device 30 from being blocked by the projection 27.

The first bottom surface 10a of the protective cover 10 and the second bottom surface 18a of the transparent plate 18 are bonded to the projection 27 by the bonding member 60 provided on the projection 27. Specifically, the bottom surface of the side plate 13, the bottom surface of the side plate 14, the bottom surface 15a of the rear wall 15, and the second bottom surface 18a of the transparent plate 18 are bonded to the projection 27 by the bonding member 60 provided on the projection 27. The bonding member 60 is, for example, an adhesive, a brazing material, solder, or a eutectic bonding metal.

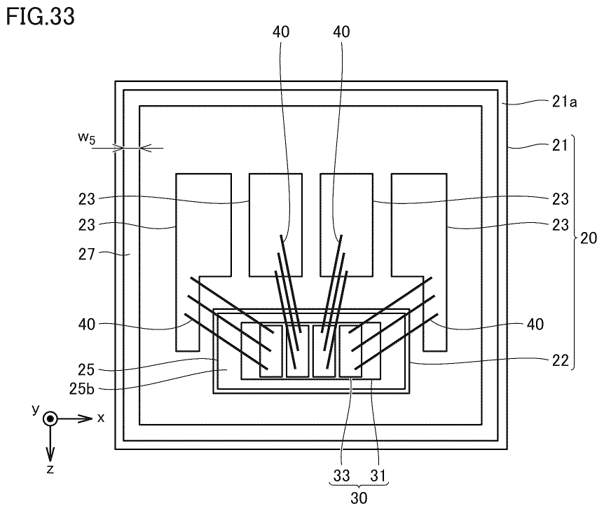

With reference to FIGS. 32 and 33, the bonding member 60 may include a fillet 61 and a fillet 62.

The fillet 61 is a portion of the bonding member 60 that protrudes toward the housing space 10h with respect to the side plate 13, the side plate 14, the rear wall 15 and the transparent plate 18. The fillet 61 is in contact with a side surface of the side plate 13 that faces the housing space 10h, a side surface of the side plate 14 that faces the housing space 10h, a side surface of the rear wall 15 that faces the housing space 10h, a side surface of the transparent plate 18 that faces the housing space 10h, and a side surface of the projection 27 that faces the housing space 10h.

The fillet 62 is a portion of the bonding member 60 that protrudes away from the housing space 10h with respect to the side plate 13, the side plate 14, the rear wall 15, and the transparent plate 18. The fillet 62 is in contact with a side surface of the side plate 13 opposite to the housing space 10h, a side surface of the side plate 14 opposite to the housing space 10h, a side surface of the rear wall 15 opposite to the housing space 10h, a side surface of the transparent plate 18 opposite to the housing space 10h, and a side surface of the projection 27 opposite to the housing space 10h.

The fillets 61 and 62 improve the bonding force between the protective case 1 and the projection 27 and the bonding force between the protective case 1 and the base substrate 20, and improve the airtightness between the protective case 1 and the projection 27 and the airtightness between the protective case 1 and the base substrate 20.

A method of manufacturing the protective case 1 according to the present embodiment will be described with reference to FIGS. 11 and 34 to 38. The method of manufacturing the protective case 1 according to the present embodiment includes the same steps as those of the method of manufacturing the protective case 1 according to the first embodiment, but is different from the method of manufacturing the protective case 1 according to the present embodiment mainly in the following points.

With reference to FIG. 11, in the method of manufacturing protective case 1 of the present embodiment, a base member 51 is prepared. The thickness of the base member 51 of the present embodiment is smaller than the thickness of the base member 51 of the first embodiment.

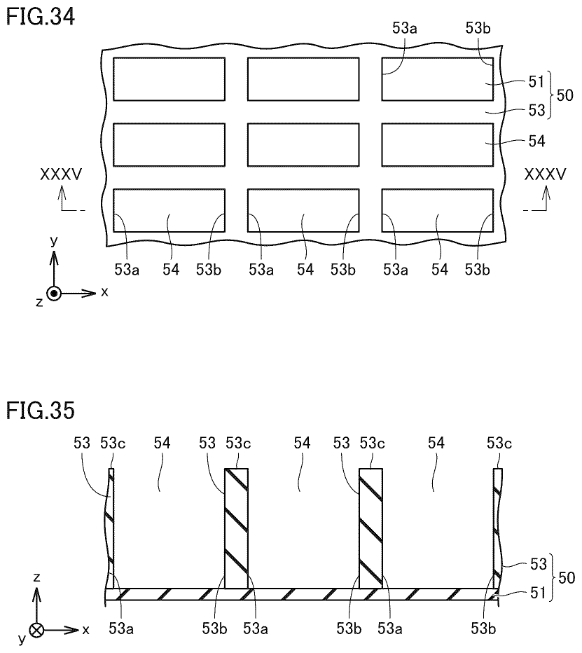

With reference to FIGS. 34 and 35, a hollow member 53 is formed on the base member 51. Thus, a protective cover array 50 that includes the base member 51 and the hollow member 53 is formed. The surface 53c of the hollow member 53 is provided with a plurality of holes 54. The distance between the holes 54 adjacent to each other is, for example, twice the thickness of the base member 51. The hollow member 53 includes a first edge 53a and a second edge 53b that define each of the plurality of holes 54. The steps of the present embodiment illustrated in FIGS. 34 and 35 are the same as the steps of the first embodiment illustrated in FIGS. 12 and 13.

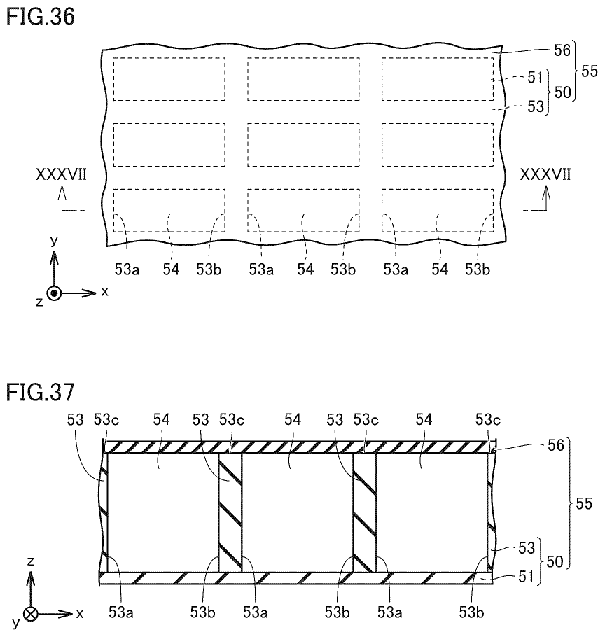

With reference to FIGS. 36 and 37, a transparent member 56 is attached to the surface 53c of the hollow member 53. The steps of the present embodiment illustrated in FIGS. 36 and 37 are the same as the steps of the first embodiment illustrated in FIGS. 14 and 15.

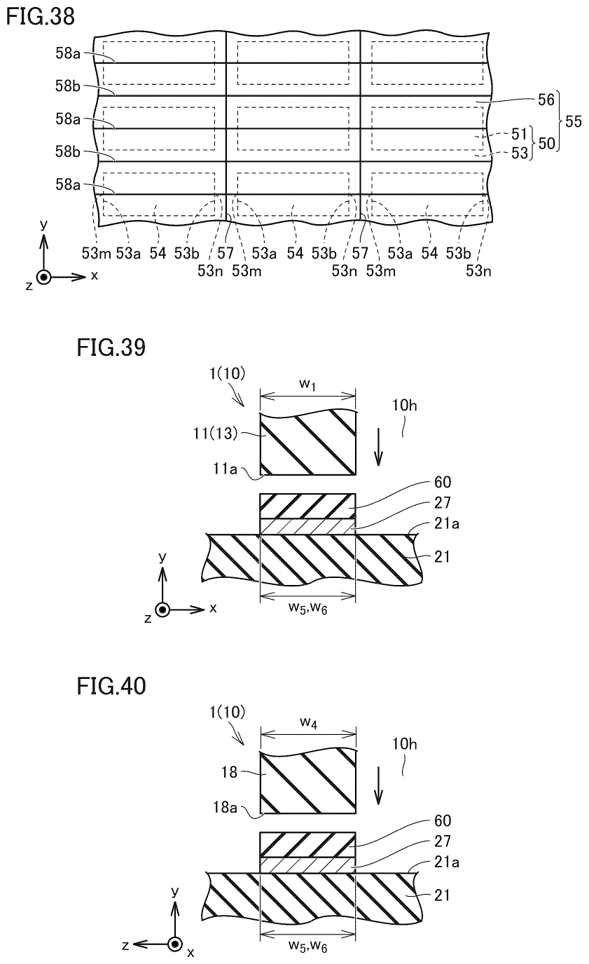

With reference to FIG. 38, the stack 55 is cut along the cutting planes 57, 58a and 58b using a dicing blade (not shown) or the like. The dicing step of the present embodiment illustrated in FIG. 38 is similar to the dicing step of the first embodiment illustrated in FIG. 16, but is different from the dicing step of the first embodiment mainly in the position of the cutting planes 58a and 58b. Specifically, the cutting plane 57 is located on a center line between the holes 54, 54 adjacent to each other in the first direction (for example, the x direction). The cutting plane 58a is located on a center line of the hole 54 in the second direction (for example, the y direction), and passes through a center 53m of the first edge 53a and a center 53n of the second edge 53b. The cutting plane 58b is parallel to the cutting plane 58a, and is located on the center line between the holes 54, 54 adjacent to each other in the second direction (for example, the y direction).

Thus, the stack 55 is diced. The base member 51 is cut to form the rear wall 15, the hollow member 53 is cut to form the cover body 11, and the transparent member 56 is cut to form the transparent plate 18. Thus, the protective case 1 is obtained. By cutting the stack 55 along the cutting plane 58a, it is possible to increase the number of protective cases 1 to be obtained from the stack 55, which makes it possible to reduce the cost of the protective case 1.

An example method of manufacturing the semiconductor light emitting apparatus 2 of the present embodiment will be described.

A submount 25 is mounted on the base substrate 20 (specifically, the main surface 21a of the insulating substrate 21) on which the projection 27 is provided. A semiconductor light emitting device 30 is mounted on the main surface 25b of the submount 25. A conductive wire 40 is bonded to the semiconductor light emitting device 30 and the first conductive member 23 of the base substrate 20.

With reference to FIGS. 39 and 40, a bonding member 60 is provided on projection 27. The bonding member 60 is prevented from significantly wetting and spreading from the projection 27 by the surface tension of the projection 27 and the bonding member 60. Since the width w₅ of the projection 27 is constant over the entire circumference of the projection 27, the width w₆ of the bonding member 60 is also constant over the entire circumference of the bonding member 60. In the present specification, the expression that the width w₆ of the bonding member 60 is constant means that the difference between the maximum value of the width of the bonding member 60 and the minimum value of the width of the bonding member 60 is 10% or less of the maximum value of the width of the bonding member 60. Therefore, for example, the bonding member 60 can be easily provided on the projection 27 by discharging the bonding member 60 from a single nozzle and coating the bonding member 60 on the projection 27.

With reference to FIGS. 39 and 40, the protective case 1 is moved toward the projection 27, and the bonding member 60 is used to fix the protective case 1 to the projection 27. Thus, the semiconductor light emitting apparatus 2 is obtained. When the width w₆ of the bonding member 60 is constant over the entire circumference of the bonding member 60, the bonding force of the bonding member 60 becomes uniform over the entire circumference of the bonding member 60. Therefore, a thermal stress resulting from the difference between the thermal expansion coefficient of the protective case 1 and the thermal expansion coefficient of the base substrate 20 is prevented from being intensively applied to a part of the protective case 1 and a part of the base substrate 20. This prevents the protective case 1 and the base substrate 20 from being damaged by the thermal stress. The pressing force of the protective case I acting on the bonding member 60 may cause the bonding member 60 to protrude from the projection 27 so as to form the fillets 61 and 62 in the bonding member 60.

The protective case for a semiconductor light emitting device (the protective case 1), the method of manufacturing the same, and the semiconductor light emitting apparatus 2 according to the present embodiment have the following effects in addition to the effects of the protective case for a semiconductor light emitting device (the protective case 1), the method of manufacturing the same, and the semiconductor light emitting apparatus 2 according to the first embodiment.

In the protective case for a semiconductor light emitting device (the protective case 1) of the present embodiment, the width (w₁, w₂, w₃) of the first bottom surface 10a of the protective cover 10 around the bottom opening 10j is equal to the width w₄ of the second bottom surface 18a of the transparent plate 18.

Therefore, it is possible to use the bonding member 60 which has a constant width to fix the protective case for a semiconductor light emitting device (the protective case 1) to the base substrate 20. The bonding member 60 can be easily provided on the projection 27 by, for example, discharging the bonding member 60 from a single nozzle and coating the bonding member 60 on the projection 27. Further, the thermal stress resulting from the difference between the thermal expansion coefficient of the protective case 1 and the thermal expansion coefficient of the base substrate 20 is prevented from being intensively applied to a part of the protective case 1 and a part of the base substrate 20. This prevents the protective case 1 and the base substrate 20 from being damaged by the thermal stress.

In the method of manufacturing the protective case for a semiconductor light emitting device (the protective case 1) of the present embodiment, the cutting plane 58a passes through the center 53m of the first edge 53a and the center 53n of the second edge 53b.

Therefore, it is possible to increase the number of protective cases 1 to be obtained from the stack 55, which makes it possible to reduce the cost of the protective case for a semiconductor light emitting device (the protective case 1).

The semiconductor light emitting apparatus 2 of the present embodiment further includes a projection 27 and a bonding member 60. The projection 27 is provided on the base substrate 20 and surrounds the semiconductor light emitting device 30. The first bottom surface 10a of the protective cover 10 and the second bottom surface 18a of the transparent plate 18 are bonded to the projection 27 by the bonding member 60 provided on the projection 27.

The bonding member 60 is prevented from significantly wetting and spreading from the projection 27 by the surface tension of the projection 27 and the bonding member 60. This prevents the positional displacement of the protective case for a semiconductor light emitting device (the protective case 1) with respect to the base substrate 20.

Although the semiconductor light emitting device 30 is a semiconductor laser device and the semiconductor light emitting apparatus 2 is a semiconductor laser device in the first to third embodiments, the semiconductor light emitting device 30 may be a light emitting diode (LED) and the semiconductor light emitting apparatus 2 may be an LED device.

It should be understood that the first to third embodiments and their modifications disclosed herein are illustrative and non-restrictive in all respects. As long as there is no contradiction, at least two of the first to third embodiments and their modifications disclosed herein may be combined. For example, the semiconductor light emitting apparatus 2 according to the first embodiment or the second embodiment may include the projection 27 and the bonding member 60 according to the third embodiment. As the positions of the cutting planes 58a and 58b in the method of manufacturing the protective case for a semiconductor light emitting device (the protective case 1) according to the second embodiment, the positions of the cutting planes 58a and 58b in the method of manufacturing the protective case for a semiconductor light emitting device (the protective case 1) according to the third embodiment may be employed. The scope of the present disclosure is defined not by the above description but by the claims, and is intended to include all changes within the meaning and scope equivalent to the claims.

### Aspects

(1) A protective case for a semiconductor light emitting device includes a protective cover in which the semiconductor light emitting device can be housed, and a transparent plate. The protective cover includes a first bottom surface, a first top surface opposite to the first bottom surface, a front surface connected to the first bottom surface and the first top surface, and a rear surface opposite to the front surface and connected to the first bottom surface and the first top surface. The first bottom surface of the protective cover faces a base substrate that supports the semiconductor light emitting device. The first bottom surface of the protective cover is provided with a bottom opening. The front surface of the protective cover is provided with a front opening that allows a light beam emitted from the semiconductor light emitting device to pass therethrough. The front opening of the protective cover extends to the first bottom surface of the protective cover. The transparent plate is attached to the front surface of the protective cover to close the front opening. The transparent plate includes a second bottom surface that faces the base substrate. The first bottom surface of the protective cover and the second bottom surface of the transparent plate are flush with each other.

(2) In the protective case for a semiconductor light emitting device according to (1), the transparent plate includes a second top surface opposite to the second bottom surface. A level difference between the first top surface of the protective cover and the second top surface of the transparent plate is 20 μm or less.

(3) In the protective case for a semiconductor light emitting device according to (1), the transparent plate includes a second top surface opposite to the second bottom surface. The first top surface of the protective cover and the second top surface of the transparent plate are flush with each other.

(4) In the protective case for a semiconductor light emitting device according to any one of (1) to (3), the protective cover includes a cover body that includes a front surface, and a rear wall that includes a rear surface and is connected to the cover body. The cover body is provided with a bottom opening and a front opening. The rear wall is a separate member from the cover body.

(5) In the protective case for a semiconductor light emitting device according to (4), the cover body is made of glass, resin, metal, or ceramic. The rear wall is made of glass, resin, metal or ceramic.

(6) In the protective case for a semiconductor light emitting device according to any one of (1) to (3), the protective cover includes a cover body that includes a front surface, and a rear wall that includes a rear surface and is connected to the cover body. The cover body is provided with a bottom opening and a front opening. The rear wall and the cover body are integrally molded as a single member.

(7) In the protective case for a semiconductor light emitting device according to (6), the cover body and the rear wall are made of glass, resin, metal, or ceramic.

(8) In the protective case for a semiconductor light emitting device according to any one of (1) to (7), a width of the first bottom surface around the bottom opening is equal to a width of the second bottom surface.

(9) A method of manufacturing a protective case for a semiconductor light emitting device includes a step of forming a protective cover array. The protective cover array includes a base member and a hollow member formed on the base member. The hollow member includes a surface opposite to the base member. The surface of the hollow member is provided with a plurality of holes. The base member is exposed from the hollow member in each of the plurality of holes. The hollow member includes a first edge and a second edge that define each of the plurality of holes. The second edge is opposed to the first edge. The method of manufacturing a protective case for a semiconductor light emitting device includes a step of attaching a transparent member to the surface of the hollow member to form a stack that includes the protective cover array and the transparent member. The plurality of holes are closed by the transparent member. The method of manufacturing a protective case for a semiconductor light emitting device includes a step of dicing the stack by cutting the stack of along a cutting plane. In a plan view of the surface of the hollow member, the cutting plane intersects the first edge and the second edge and passes through an inside of each of the plurality of holes.

(10) In the method of manufacturing a protective case for a semiconductor light emitting device according to (9), the step of forming the protective cover array includes a step of preparing a base member and a step of forming a hollow member on the base member.

(11) In the method of manufacturing a protective case for a semiconductor light emitting device according to (9), the step of forming the protective cover array includes integrally molding the base member and the hollow member.

(12) In the method of manufacturing a protective case for a semiconductor light emitting device according to any one of (9) to (11), the cutting plane passes through a center of the first edge and a center of the second edge.

(13) A semiconductor light emitting apparatus includes the protective case for a semiconductor light emitting device according to any one of (1) to (8), the semiconductor light emitting device, and the base substrate that supports the semiconductor light emitting device.

(14) The semiconductor light emitting apparatus according to (13) further includes a projection provided on the base substrate and surrounding the semiconductor light emitting device, and a bonding member. The first bottom surface of the protective cover and the second bottom surface of the transparent plate are bonded to the projection by the bonding member provided on the projection.

### REFERENCE SIGNS LIST

1: protective case; 2: semiconductor light emitting apparatus; 10: protective cover; 10a: first bottom surface; 10b: first top surface; 10c: front surface; 10d: rear surface; 10h: housing space; 10i: front opening; 10j: bottom opening; 11: cover body; 11a: bottom surface; 11b: top surface; 11c: front surface; 11d: rear surface; 12: top plate; 13, 14: side plate; 15: rear wall; 15a: bottom surface; 15b: top surface; 18: transparent plate; 18a: second bottom surface; 18b: second top surface; 20: base substrate; 21: insulating substrate; 21a, 21b: main surface; 22: second conductive member; 23: first conductive member; 25: submount; 25a, 25b: main surface; 27: projection; 30: semiconductor light emitting device; 31: semiconductor main body; 32: second electrode; 33: first electrode; 34: light emitting layer; 35: light beam; 40: conductive wire; 50: protective cover array; 51: base member; 53: hollow member; 53a: first edge; 53b: second edge; 53c: surface; 54: hole; 55: stack; 56: transparent member; 57, 58a, 58b: cross section; 60: bonding member; 61, 62: fillet.

1. A protective case for a semiconductor light emitting device, the protective case comprising:
a protective cover in which the semiconductor light emitting device can be housed; and
a transparent plate,
wherein the protective cover includes a first bottom surface facing a base substrate that supports the semiconductor light emitting device, a first top surface opposite to the first bottom surface, a front surface connected to the first bottom surface and the first top surface, and a rear surface opposite to the front surface and connected to the first bottom surface and the first top surface,
the first bottom surface is provided with a bottom opening,
the front surface is provided with a front opening that allows a light beam emitted from the semiconductor light emitting device to pass therethrough, and the front opening extends to the first bottom surface,
the transparent plate is attached to the front surface to close the front opening, and includes a second bottom surface that faces the base substrate,
the first bottom surface of the protective cover and the second bottom surface of the transparent plate are flush with each other.

2. The protective case for a semiconductor light emitting device according to claim 1, wherein
the transparent plate includes a second top surface opposite to the second bottom surface, and
a level difference between the first top surface of the protective cover and the second top surface of the transparent plate is 20 μm or less.

3. The protective case for a semiconductor light emitting device according to claim 1, wherein
the transparent plate includes a second top surface opposite to the second bottom surface, and
the first top surface of the protective cover and the second top surface of the transparent plate are flush with each other.

4. The protective case for a semiconductor light emitting device according to claim 1, wherein
the protective cover includes a cover body that includes the front surface, and a rear wall that includes the rear surface and is connected to the cover body,
the cover body is provided with the bottom opening and the front opening, and
the rear wall is a separate member from the cover body.

5. The protective case for a semiconductor light emitting device according to claim 4, wherein
the cover body is made of glass, resin, metal, or ceramic, and
the rear wall is made of glass, resin, metal or ceramic.

6. The protective case for a semiconductor light emitting device according to claim 1, wherein
the protective cover includes a cover body that includes the front surface, and a rear wall that includes the rear surface and is connected to the cover body,
the cover body is provided with the bottom opening and the front opening, and
the rear wall and the cover body are integrally molded as a single member.

7. The protective case for a semiconductor light emitting device according to claim 6, wherein
the cover body and the rear wall are made of glass, resin, metal or ceramic.

8. The protective case for a semiconductor light emitting device according to claim 1, wherein
a width of the first bottom surface around the bottom opening is equal to a width of the second bottom surface.

9. A method of manufacturing a protective case for a semiconductor light emitting device, the method comprising:
a step of forming a protective cover array, wherein the protective cover array includes a base member and a hollow member formed on the base member, the hollow member includes a surface opposite to the base member, the surface is provided with a plurality of holes, the base member is exposed from the hollow member in each of the plurality of holes, the hollow member includes a first edge and a second edge that define each of the plurality of holes, and the second edge is opposed to the first edge,
a step of attaching a transparent member to the surface of the hollow member to form a stack that includes the protective cover array and the transparent member, wherein the plurality of holes are closed by the transparent member,
a step of dicing the stack by cutting the stack along a cutting plane, wherein the cutting plane intersects the first edge and the second edge, and passes through an inside of each of the plurality of holes in a plan view of the surface.

10. The method of manufacturing a protective case for a semiconductor light emitting device according to claim 9, wherein
the step of forming the protective cover array includes a step of preparing the base member and a step of forming the hollow member on the base member.

11. The method of manufacturing a protective case for a semiconductor light emitting device according to claim 9, wherein
the step of forming the protective cover array includes integrally molding the base member and the hollow member.

12. The method of manufacturing a protective case for a semiconductor light emitting device according to claim 9, wherein
the cutting plane passes through a center of the first edge and a center of the second edge.

13. A semiconductor light emitting apparatus comprising:
the protective case for a semiconductor light emitting device according to claim 1;
the semiconductor light emitting device; and
the base substrate that supports the semiconductor light emitting device.

14. The semiconductor light emitting apparatus according to claim 13 further comprising:
a projection provided on the base substrate and surrounding the semiconductor light emitting device; and
a bonding member,
wherein the first bottom surface of the protective cover and the second bottom surface of the transparent plate are bonded to the projection by the bonding member provided on the projection.
